(19) United States
(12) Patent Application Publication
(10) Pub. No.: US 2026/0190243 A1
(43) Pub. Date: Jul. 2, 2026

(54) METHOD FOR MANUFACTURING WIRING SUBSTRATE, AND WIRING SUBSTRATE

(71) Applicant: IBIDEN CO., LTD., Gifu (JP)

(72) Inventor: Nobuhisa KURODA, Gifu (JP)

(73) Assignee: IBIDEN CO., LTD., Gifu (JP)

(21) Appl. No.: 19/429,272

(22) Filed: Dec. 22, 2025

(30) Foreign Application Priority Data
Dec. 26, 2024 (JP) 2024-230600

(51) Int. Cl. H05K 3/00; H05K 1/03

(52) U.S. Cl. CPC H05K 3/0044; H05K 1/0306; H05K 2203/0228

(57) ABSTRACT

A method for manufacturing a wiring substrate includes forming a laminate including a core substrate, a first build-up part, and a second build-up part, forming a first groove on the laminate from surface of the laminate on a first build-up part side such that the first groove is formed in the first build-up part, forming a second groove on the laminate from surface of the laminate on a second build-up part side such that the second groove is formed in the second build-up part and has center of width that is offset from center of width of the first groove, and cutting the core substrate along one of the first and the second grooves such that the laminate is divided into multiple wiring substrates. The first build-up part is formed on first surface of the core substrate. The second build-up part is formed on second surface of the core substrate.

### CROSS-REFERENCE TO RELATED APPLICATIONS

The present application is based upon and claims the benefit of priority to Japanese Patent Application No. 2024-230600, filed Dec. 26, 2024, the entire contents of which are incorporated herein by reference.

### BACKGROUND OF THE INVENTION

### Field Of The Invention

The present invention relates to a method for manufacturing a wiring substrate and a wiring substrate.

### Description of Background Art

Japanese Patent Application Laid-Open Publication No. 2015-231005 describes a method for manufacturing a wiring substrate. The entire contents of this publication are incorporated herein by reference.

### SUMMARY OF THE INVENTION

According to one aspect of the present invention, a method for manufacturing a wiring substrate includes forming a laminate including a core substrate, a first build-up part, and a second build-up part, forming a first groove on the laminate from a surface of the laminate on a first build-up part side such that the first groove is formed in the first build-up part, forming a second groove on the laminate from a surface of the laminate on a second build-up part side such that the second groove is formed in the second build-up part and has a center of a width that is offset from a center of a width of the first groove, and cutting the core substrate in the laminate along one of the first groove in the first build-up part and the second groove in the second build-up part such that the laminate is divided into multiple wiring substrates. The laminate is formed such that the first build-up part is formed on a first surface of the core substrate and that the second build-up part is formed on a second surface of the core substrate on the opposite side with respect to the first surface of the core substrate.

According to another aspect of the present invention, a wiring substrate includes a core substrate, a first build-up part laminated on a first surface of the core substrate, and a second build-up part laminated on a second surface of the core substrate on the opposite side with respect to the first surface of the core substrate. At least a portion of a side surface of one of the first build-up part and the second build-up part is formed on an inner side of a side surface of the other one of the first build-up part and the second build-up part.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a cross-sectional view illustrating a first modified example of a wiring substrate according to an embodiment of the present invention;

FIG. 3 is a cross-sectional view illustrating a second modified example of a wiring substrate according to an embodiment of the present invention;

FIG. 4A is a cross-sectional view illustrating an example of a method for manufacturing a wiring substrate according to an embodiment of the present invention;

FIG. 4B is a cross-sectional view illustrating an example of a method for manufacturing a wiring substrate according to an embodiment of the present invention;

FIG. 4C is a cross-sectional view illustrating an example of a method for manufacturing a wiring substrate according to an embodiment of the present invention;

FIG. 4D is a cross-sectional view illustrating an example of a method for manufacturing a wiring substrate according to an embodiment of the present invention;

FIG. 5A is a cross-sectional view illustrating an example of a method for manufacturing a wiring substrate according to an embodiment of the present invention;

FIG. 5B is a plan view illustrating an example of a method for manufacturing a wiring substrate according to an embodiment of the present invention;

FIG. 5C is a cross-sectional view illustrating an example of a method for manufacturing a wiring substrate according to an embodiment of the present invention;

FIG. 6A is a cross-sectional view illustrating a first modified example of formation of grooves in a method for manufacturing a wiring substrate according to an embodiment of the present invention;

FIG. 6B is a cross-sectional view illustrating a second modified example of the formation of the grooves in a method for manufacturing a wiring substrate according to an embodiment of the present invention;

FIG. 7A is a cross-sectional view illustrating a first modified example of cutting of a core substrate in a method for manufacturing a wiring substrate according to an embodiment of the present invention;

FIG. 7B is a cross-sectional view illustrating a second modified example of the cutting of the core substrate in a method for manufacturing a wiring substrate according to an embodiment of the present invention; and FIG. 7C is a cross-sectional view illustrating a third modified example of the cutting of the core substrate in a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

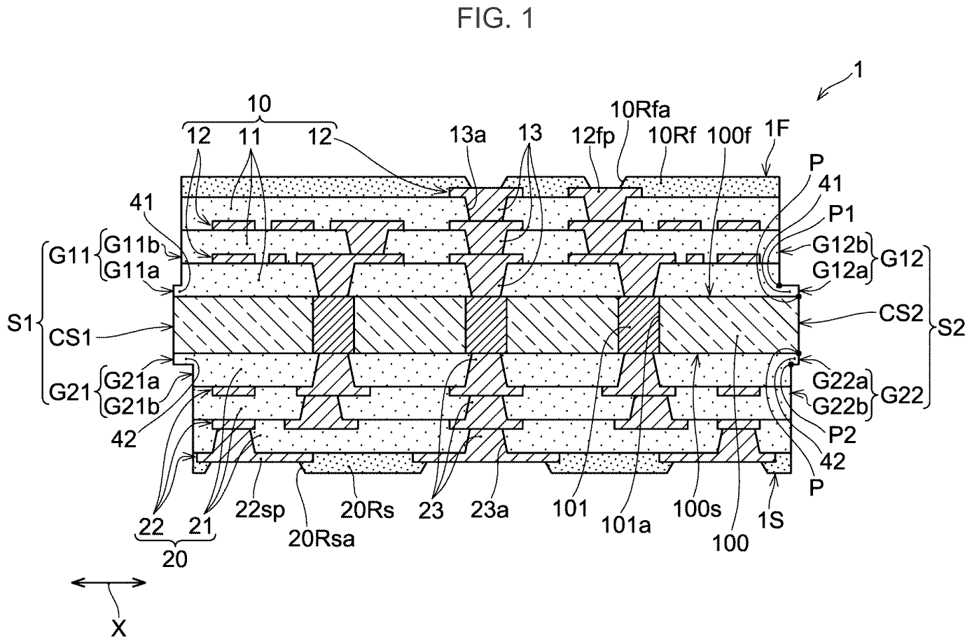

FIG. 1 illustrates a cross-sectional view of a wiring substrate 1 according to an embodiment of the present invention and also an example of a wiring substrate manufactured using a method for manufacturing a wiring substrate according to an embodiment of the present invention. For example, a laminated structure of the wiring substrate of the embodiment or of a wiring substrate manufactured using the method for manufacturing a wiring substrate of the embodiment, as well as the number of conductor layers and insulating layers included in these wiring substrates, may differ from the laminated structure of the wiring substrate 1 illustrated in FIG. 1 and the number of the conductor layers and insulating layers included in the wiring substrate 1.

The wiring substrate 1 includes a core substrate 100, and a first build-up part 10 and a second build-up part 20 that are respectively formed by alternately laminated insulating layers and conductor layers on two surfaces of the core substrate 100. The wiring substrate 1 has, as two main surfaces orthogonal to its thickness direction, a surface (1F) and a surface (1S) on an opposite side with respect to the surface (1F).

The core substrate 100 included in the wiring substrate 1 has a first surface (100f) and a second surface (100s) on an opposite side with respect to the first surface (100f). On the first surface (100f) of the core substrate 100, the first build-up part 10 is formed by alternately laminating multiple first insulating layers 11 and multiple first conductor layers 12. On the second surface (100s) of the core substrate 100, the second build-up part 20 is formed by alternately laminating multiple second insulating layers 21 and multiple second conductor layers 22.

In the description of the wiring substrate 1 of the embodiment, a side closer to the core substrate 100 is referred to as “lower,” “inner,” or “lower side” or “inner side,” and a side farther from the core substrate 100 is referred to as “upper,” “outer,” or “upper side” or “outer side.” For each element constituting the wiring substrate 1, a surface facing the core substrate 100 is also referred to as a “lower surface,” and a surface facing away from the core substrate 100 is also referred to as an “upper surface.”

In the core substrate 100, through conductors 101 penetrating the core substrate 100 in its thickness direction are formed. In each first insulating layer 11 constituting the first build-up part 10, first via conductors 13 are formed that connect conductors facing each other with the first insulating layer 11 interposed therebetween. In each second insulating layer 21 constituting the second build-up part 20, second via conductors 23 are formed that connect conductors facing each other with the second insulating layer 21 interposed therebetween.

The through conductors 101 are formed by filling through holes (101a) formed in the core substrate 100 with a conductive material. Each first via conductor 13 is formed by filling a through hole (13a) formed in a first insulating layer 11 with a conductive material, and is integrally formed with a first conductor layer 12 positioned on an upper side of the first via conductor 13. Each second via conductor 23 is formed by filling a through hole (23a) formed in a second insulating layer 21 with a conductive material, and is integrally formed with a second conductor layer 22 positioned on an upper side of the second via conductor 23.

The core substrate 100 included in the wiring substrate 1 may be a silicon substrate, a ceramic substrate, a resin substrate, or the like. A material of the core substrate 100 is not particularly limited. Further, the core substrate 100 may be formed of glass. Therefore, the core substrate 100 may include a glass plate or may be constituted by a glass plate. As a glass material used for the glass plate constituting the core substrate 100, for example, soda-lime glass, borosilicate glass, alkali-free glass, or the like can be used. These glasses may contain, as additives, elements such as magnesium, calcium, manganese, aluminum, lead, iron, chromium, potassium, sulfur, antimony, and boron.

The first insulating layers 11 and the second insulating layers 21 are formed using any insulating resin. Examples of the insulating resin include: thermosetting resins such as epoxy resins, bismaleimide triazine resins (BT resins), or phenolic resins; and thermoplastic resins such as fluorine resins, liquid crystal polymers (LCP), fluoroethylene (PTFE) resins, polyester (PE) resins, and modified polyimide (MPI) resins. The first insulating layers 11 and the second insulating layers 21 can contain an inorganic filler (not illustrated) such as silica or alumina. The first insulating layers 11 and the second insulating layers 21 may also contain a reinforcing material (core material) such as glass fiber or aramid fiber.

Examples of conductive materials constituting the first conductor layers 12, the second conductor layers 22, the first via conductors 13, the second via conductors 23, and the through conductors 101 include copper, nickel, titanium, tungsten, palladium, and the like. These conductors are preferably made of copper. In the example illustrated in FIG. 1, the first conductor layers 12, the second conductor layers 22, the first via conductors 13, the second via conductors 23, and the through conductors 101 are each illustrated as being constituted by a single layer, but they may each have a multilayer structure formed by a metal foil, an electroless plating film, a sputtering film, and/or an electrolytic plating film.

The first conductor layers 12 and the second conductor layers 22 each include predetermined conductor patterns. The first conductor layer 12 that constitutes the surface (1F) of the wiring substrate 1 includes multiple conductor pads (12fp). The second conductor layer 22 that constitutes the surface (1S) of the wiring substrate 1 includes multiple conductor pads (22sp).

The wiring substrate 1 includes, on the surface (1F) side, a solder resist layer (10Rf) that covers the first build-up part 10. Openings (10Rfa) are formed in the solder resist layer (10Rf), and the conductor pads (12fp) are exposed from the openings (10Rfa). The wiring substrate 1 further includes, on the surface (1S) side, a solder resist layer (20Rs) that covers the second build-up part 20. Openings (20Rsa) are formed in the solder resist layer (20Rs), and the conductor pads (22sp) are exposed from the openings (20Rsa). The solder resist layer (10Rf) and the solder resist layer (20Rs) may be formed of, for example, a photosensitive polyimide resin or epoxy resin.

The surface (1F) of the wiring substrate 1 in the illustrated example may serve as a component mounting surface to which an external electronic component (not illustrated) is connected. The conductor pads (12fp) may be connected to electrodes of an external electronic component when the wiring substrate 1 is in use. When the wiring substrate 1 is in use, the wiring substrate 1 may be connected to an external substrate (not illustrated), which is, for example, a motherboard of any electrical device, with the surface (1S) facing the external substrate. In such a case, the conductor pads (22sp) may be used for connection to the external substrate.

The wiring substrate of the embodiment, such as the wiring substrate 1 illustrated in FIG. 1, is manufactured, as described later, by dividing and singulating a laminate of conductor layers and insulating layers, including multiple wiring substrates, into individual wiring substrates. Sidewalls of the individual wiring substrates are exposed by this singulation. In a singulation process in the method for manufacturing a wiring substrate of the embodiment to be described later, a laminate of conductor layers and insulating layers is divided into individual wiring substrates using a method in which unintended cracking is unlikely to occur in a core substrate. Therefore, it is thought that the wiring substrate of the embodiment, such as the wiring substrate 1 illustrated in FIG. 1, can be formed with good yield, and occurrence of defects during use due to manifestation of latent cracks or the like can also be suppressed. The “sidewalls” of the wiring substrate 1 are outer wall surfaces of the wiring substrate 1 that connect the surface (1F) and the surface (1S) along the thickness direction of the wiring substrate 1.

The wiring substrate of the embodiment may have two opposing sidewalls, such as a sidewall (S1) (first sidewall) and a sidewall (S2) (second sidewall) illustrated in FIG. 1. Further, the wiring substrate of the embodiment may have two pairs of opposing sidewalls. That is, the wiring substrate of the embodiment may have a rectangular shape in plan view, and multiple wiring substrates may be connected in a lattice pattern until singulation. The term “plan view” means viewing an object along the thickness direction of the wiring substrate of the embodiment. Further, the term “planar shape” used in the following description means a shape of each object as observed in plan view.

In the wiring substrate 1 illustrated in FIG. 1, the sidewall (S1) of the wiring substrate 1 is constituted by a side surface (G11) of the first build-up part 10, a side surface (CS1) of the core substrate 100, and a side surface (G21) of the second build-up part 20. The side surface (G11) of the first build-up part 10 is constituted by a first portion (G11a) that is formed on the core substrate 100 side and in contact with the side surface (CS1) of the core substrate 100, and a second portion (G11b) that is formed on a surface layer side of the wiring substrate 1 and in contact with the surface (1F). The first portion (G11a) is also a portion of the side surface (G11) that is flush with the side surface (CS1) of the core substrate 100. The side surface (G11) of the first build-up part 10 has a step between the first portion (G11a) and the second portion (G11b). The side surface (G21) of the second build-up part 20 is constituted by a first portion (G21a) that is formed on the core substrate 100 side and in contact with the side surface (CS1) of the core substrate 100, and a second portion (G21b) that is formed on a surface layer side of the wiring substrate 1 and in contact with the surface (1S). The first portion (G21a) is also a portion of the side surface (G21) that is flush with the side surface (CS1) of the core substrate 100. The side surface (G21) of the second build-up part 20 has a step between the first portion (G21a) and the second portion (G21b).

On the other hand, the sidewall (S2) of the wiring substrate 1 is constituted by a side surface (G12) of the first build-up part 10, a side surface (CS2) of the core substrate 100, and a side surface (G22) of the second build-up part 20. The side surface (G12) of the first build-up part 10 is constituted by a first portion (G12a) that is formed on the core substrate 100 side and in contact with the side surface (CS2) of the core substrate 100, and a second portion (G12b) that is formed on a surface layer side of the wiring substrate 1 and in contact with the surface (1F). The first portion (G12a) is also a portion of the side surface (G12) that is flush with the side surface (CS2) of the core substrate 100. The side surface (G12) of the first build-up part 10 has a step between the first portion (G12a) and the second portion (G12b). The side surface (G22) of the second build-up part 20 is constituted by a first portion (G22a) that is formed on the core substrate 100 side and in contact with the side surface (CS2) of the core substrate 100, and a second portion (G22b) that is formed on a surface layer side of the wiring substrate 1 and in contact with the surface (1S). The first portion (G22a) is also a portion of the side surface (G22) that is flush with the side surface (CS2) of the core substrate 100. The side surface (G22) of the second build-up part 20 has a step between the first portion (G22a) and the second portion (G22b).

Further, in the wiring substrate 1, as illustrated in FIG. 1, at each of the sidewall (S1) and the sidewall (S2), at least a portion of one of the side surfaces of the first build-up part 10 and the second build-up part 20 is formed on an inner side of the other side surface in the wiring substrate 1 in plan view. Further, in the wiring substrate 1 illustrated in FIG. 1, at each of the sidewall (S1) and the sidewall (S2), the side surface of the core substrate 100 protrudes beyond at least a portion of the side surface of the first build-up part 10 and at least a portion of the side surface of the second build-up part 20.

Specifically, on the sidewall (S1) side of the wiring substrate 1 in the example of FIG. 1, the second portion (G21b), which is part of the side surface (G21) of the second build-up part 20, is formed on an inner side of the first portion (G11a) and the second portion (G11b) of the side surface (G11) of the first build-up part 10 in the wiring substrate 1. In other words, the first portion (G11a) and the second portion (G11b) of the side surface (G11) of the first build-up part 10 are formed on an outer side of the second portion (G21b) of the side surface (G21) of the second build-up part 20. The side surface (CS1) of the core substrate 100 is also formed on an outer side of the second portion (G21b) of the side surface (G21) of the second build-up part 20 in the wiring substrate 1.

On the other hand, on the sidewall (S2) side of the wiring substrate 1 in the example of FIG. 1, the second portion (G12b), which is part of the side surface (G12) of the first build-up part 10, is formed on an inner side of the first portion (G22a) and the second portion (G22b) of the side surface (G22) of the second build-up part 20 in the wiring substrate 1. In other words, the first portion (G22a) and the second portion (G22b) of the side surface (G22) of the second build-up part 20 are formed on an outer side of the second portion (G12b) of the side surface (G12) of the first build-up part 10. The side surface (CS2) of the core substrate 100 is also formed on an outer side of the second portion (G12b) of the side surface (G12) of the first build-up part 10 in the wiring substrate 1.

That is, in the wiring substrate 1 of the embodiment, at least a portion of the side surface (G11) of the first build-up part 10 and at least a portion of the side surface (G21) of the second build-up part 20 do not overlap in plan view. Further, at least a portion of the side surface (G12) of the first build-up part 10 and at least a portion of the side surface (G22) of the second build-up part 20 do not overlap in plan view. Further, the side surface (CS1) of the core substrate 100 does not entirely overlap, in plan view, with the side surface (G11) of the first build-up part 10 and the side surface (G21) of the second build-up part 20. Similarly, the side surface (CS2) of the core substrate 100 does not entirely overlap, in plan view, with the side surface (G12) of the first build-up part 10 and the side surface (G22) of the second build-up part 20.

In this way, in the wiring substrate of the embodiment, since at least a portion of the side surface of the first build-up part and at least a portion of the side surface of the second build-up part do not overlap, it is thought that stress generated in the core substrate or each build-up part is dispersed. That is, when the entire side surface of the first build-up part and the entire side surface of the second build-up part are flush with each other, it is thought that stress generated due to a difference in thermal expansion coefficient between each build-up part and the core substrate in response to ambient temperature changes is concentrated at interfaces between each build-up part and the core substrate at both ends of the wiring substrate. For example, on the sidewall (S2) side in FIG. 1, it is presumed that stress is likely to concentrate at two locations indicated by points (P). On the side wall (S1) side as well, it is thought that stress is likely to concentrate at similar locations.

However, in the wiring substrate of the present embodiment, since the side surface of the core substrate 100 does not overlap with at least a portion of the side surfaces of the first build-up part 10 and the side surface of the second build-up part 20, stress concentration locations are dispersed. For example, in FIG. 1, stress concentration occurring on the sidewall (S2) side of the wiring substrate 1 is dispersed to locations including not only the points (P), but also a point (P1) formed at a step location between the second portion (G12b) and the first portion (G12a) of the side surface (G12) of the first build-up part 10. Further, stress concentration occurring on the sidewall (S2) side is also dispersed to a point (P2) formed at a step location between the second portion (G22b) and the first portion (G22a) of the side surface (G22) of the second build-up part 20. On the side wall (S1) side as well, stress concentration locations are similarly dispersed. Further, the point (P1) and the point (P2) do not overlap in plan view. That is, since the stress concentration locations are dispersed to different locations in plan view on the first build-up part 10 side and on the second build-up part 20 side, it is thought that occurrence of cracking of the core substrate 100 or peeling of each build-up part from the core substrate 100 due to excessive stress concentration can be suppressed.

Further, in the wiring substrate 1 illustrated in FIG. 1, at one of the opposing sidewall (S1) and sidewall (S2), at least a portion of the side surface of the first build-up part 10 is formed on an inner side of the side surface of the second build-up part 20 in plan view. And, at the other one of the sidewall (S1) and the sidewall (S2), the side surface of the first build-up part 10 is formed on an outer side of at least a portion of the side surface of the second build-up part 20. That is, in the example of FIG. 1, at the sidewall (S2) of the wiring substrate 1, the second portion (G12b) of the side surface (G12) of the first build-up part 10 is formed on an inner side of the side surface (G22) of the second build-up part 20. And, at the sidewall (S1), the side surface (G11) of the first build-up part 10 is formed on an outer side of the second portion (G21b) of the side surface (G21) of the second build-up part 20 in the wiring substrate 1 in plan view.

Therefore, in a direction in which the sidewall (S1) and the sidewall (S2) face each other (a direction indicated by arrow (X) in FIG. 1, also referred to below as the “X direction”), a center-of-gravity position of the first build-up part 10 and a center-of-gravity position of the second build-up part 20 are offset from each other and do not overlap. Therefore, when warpage occurs in each of the first build-up part 10 and the second build-up part 20 due to temperature changes, it is thought that centers of warpage occurring in the respective build-up parts do not overlap in plan view. Therefore, it is thought that, compared to a case where the centers of warpage occurring in the respective build-up parts overlap in plan view, a load imposed on the core substrate 100 due to temperature changes is reduced. Therefore, it is inferred that occurrence of cracking in the core substrate 100 and the like can be suppressed.

As one aspect of the wiring substrate 1 that includes the first build-up part 10 and the second build-up part 20 whose center-of-gravity positions do not overlap each other in the X direction, the wiring substrate of the embodiment may have a point-symmetrical shape with respect to a center of the core substrate in a cross section taken along its thickness direction.

In the wiring substrate 1, a conductor layer such as a first conductor layer 12 or a second conductor layer 22 may be formed directly, without an intervening insulating layer, on the first surface (100f) or on the second surface (100s) of the core substrate 100. In this case, at the sidewall (S1) side of the wiring substrate 1, a portion of a conductor layer directly formed on the first surface (100f) may be exposed between the side surface (G11) of the first build-up part 10 and the side surface (CS1) of the core substrate 100.

Similarly, a portion of a conductor layer directly formed on the second surface (100s) may be exposed between the side surface (G21) of the second build-up part 20 and the side surface (CS1) of the core substrate 100. Similarly, on the side wall (S2) side of the wiring substrate 1, a portion of a conductor layer directly formed on the first surface (100f) of the core substrate 100 and/or a portion of a conductor layer directly formed on the second surface (100s) may be exposed.

In the wiring substrate 1 of the example illustrated in FIG. 1, at each of end portions on the sidewall (S1) side and on the sidewall (S2) side of the wiring substrate 1, the first build-up part 10 has a thin layer portion 41, and the second build-up part 20 has a thin layer portion 42. The thin layer portion 41 is a portion of the first build-up part 10 that has a smaller thickness than a thickness of a central portion of the first build-up part 10, and the thin layer portion 42 is a portion of the second build-up part 20 that has a smaller thickness than a thickness of a central portion of the second build-up part 20. The thicknesses of the thin layer portion 41 and the thin layer portion 42 may be, for example, 0.3 μm or more and 40 μm or less. The thin layer portion 41 and the thin layer portion 42 may protect the core substrate 100 from external impacts or the like.

On the sidewall (S1) side, the thin layer portion 41 covers the first surface (100f) of the core substrate 100 between the first portion (G11a) and the second portion (G11b) of the side surface (G11) of the first build-up part 10. Further, on the sidewall (S2) side, the thin layer portion 41 covers the first surface (100f) of the core substrate 100 between the first portion (G12a) and the second portion (G12b) of the side surface (G12) of the first build-up part 10. In the example of FIG. 1, the thin layer portion 41 is formed by a portion of the first insulating layer 11 that is directly formed on the core substrate 100 among the multiple first insulating layers 11.

On the sidewall (S1) side, the thin layer portion 42 covers the second surface (100s) of the core substrate 100 between the first portion (G21a) and the second portion (G21b) of the side surface (G21) of the second build-up part 20. Further, on the sidewall (S2) side, the thin layer portion 42 covers the second surface (100s) of the core substrate 100 between the first portion (G22a) and the second portion (G22b) of the side surface (G22) of the second build-up part 20. In the example of FIG. 1, the thin layer portion 42 is formed by a portion of the second insulating layer 21 that is directly formed on the core substrate 100 among the multiple second insulating layers 21.

It is also possible that at each of the end portions of the core substrate 100 on the sidewall (S1) side and on the sidewall (S2) side of the wiring substrate 1, a portion of the first surface (100f) and/or a portion of the second surface (100s) of the core substrate 100 are exposed without being covered by the first insulating layer 11 or the second insulating layer 21. That is, it is also possible that the thin layer portion 41 and/or the thin layer portion 42 are not provided. For example, on the sidewall (S1) side of the wiring substrate 1, the side surface (G11) of the first build-up part 10 and the side surface (G21) of the second build-up part 20 may each have only a portion formed on an inner side of the side surface (CS1) of the core substrate 100 in the wiring substrate 1. Similarly, on the sidewall (S2) side, the side surface (G12) of the first build-up part 10 and the side surface (G22) of the second build-up part 20 may each have only a portion formed on an inner side of the side surface (CS2) of the core substrate 100 in the wiring substrate 1.

### Modified Examples of Wiring Substrate

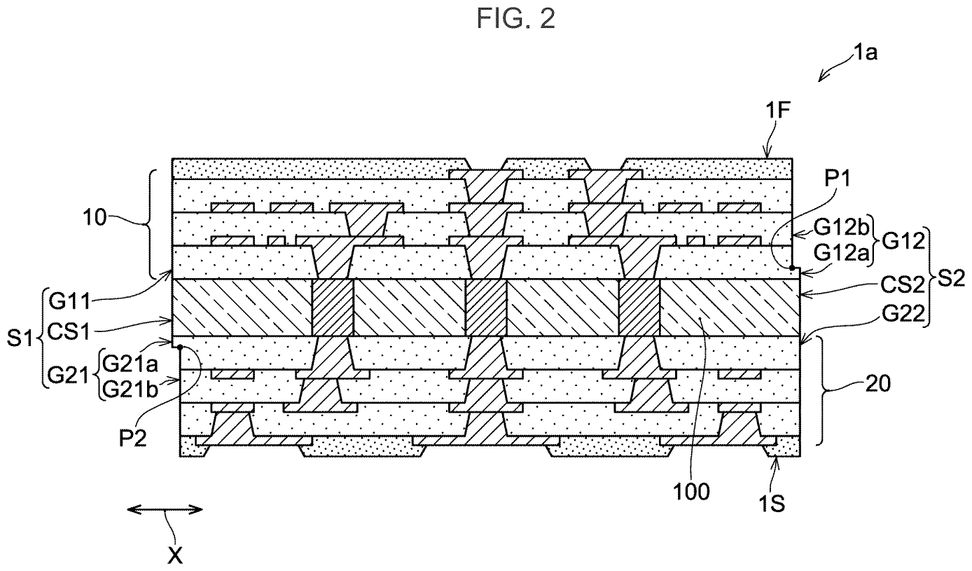

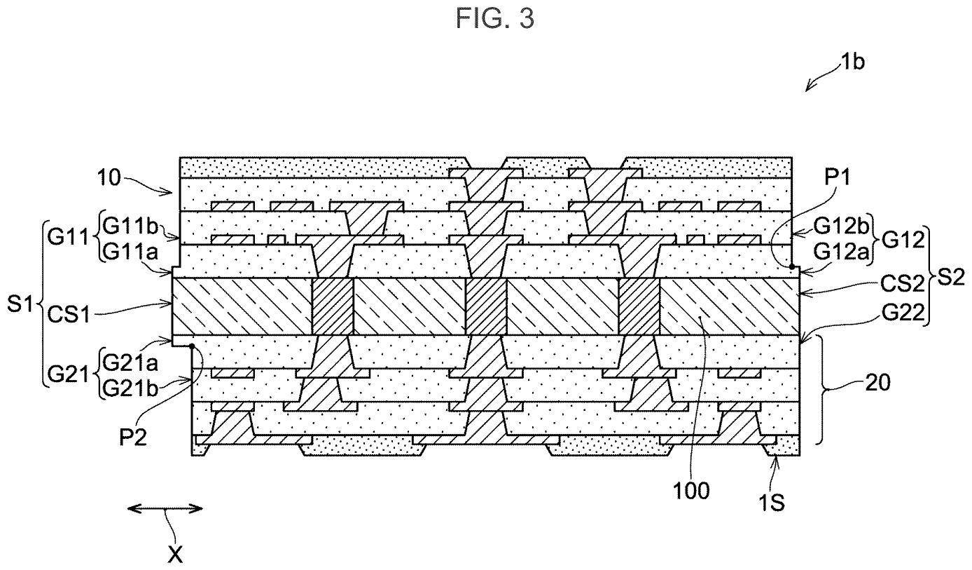

FIGS. 2 and 3 respectively illustrate a wiring substrate (1a), which is a first modified example of the wiring substrate of the embodiment, and a wiring substrate (1b), which is a second modified example of the wiring substrate of the embodiment. With reference to FIGS. 2 and 3, the modified examples of the wiring substrate of the embodiment are described below with respect to differences from the wiring substrate 1 illustrated in FIG. 1. In FIGS. 2 and 3, a structural element that is the same as a structural element of the wiring substrate 1 illustrated in FIG. 1 is denoted using the same reference numeral symbol as the one used in FIG. 1 or is omitted, and repetitive description of the same structural element is omitted as appropriate.

In the wiring substrate (1a) of FIG. 2, at the sidewall (S1), the first build-up part 10 has an entirely flat side surface (G11). The side surface (G11) is in contact with the side surface (CS1) of the core substrate 100 at one end and in contact with the surface (1F) of the wiring substrate (1a) at the other end. The side surface (G11) is flush with the side surface (CS1) of the core substrate 100. Further, at the sidewall (S1), the second build-up part 20 has a side surface (G21) that includes a first portion (G21a) and a second portion (G21b), similar to the second build-up part 20 of the wiring substrate 1 in FIG. 1. The second portion (G21b) of the side surface (G21) of the second build-up part 20 is formed on an inner side of the side surface (G11) of the first build-up part 10 and the side surface (CS1) of the core substrate 100 in the wiring substrate (1a).

On the other hand, at the sidewall (S2), the second build-up part 20 has an entirely flat side surface (G22). The side surface (G22) is in contact with the side surface (CS2) of the core substrate 100 at one end and in contact with the surface (1S) of the wiring substrate (1a) at the other end. The side surface (G22) is flush with the side surface (CS2) of the core substrate 100. Further, at the sidewall (S2), the first build-up part 10 has a side surface (G12) that includes a first portion (G12a) and a second portion (G12b), similar to the first build-up part 10 of the wiring substrate 1 in FIG. 1. The second portion (G12b) of the side surface (G12) of the first build-up part 10 is formed on an inner side of the side surface (G22) of the second build-up part 20 and the side surface (CS2) of the core substrate 100 in the wiring substrate (1a).

In the wiring substrate (1a) as well, as described above with respect to the wiring substrate 1, it is thought that locations of stress concentration that may occur in the wiring substrate (1a) are dispersed to include a location indicated by the point (P1) and a location indicated by the point (P2). Therefore, it is thought that cracking in the core substrate 100 or peeling of each build-up part from the core substrate 100 can be suppressed.

Further, in the wiring substrate (1a) as well, at the sidewall (S2), the second portion (G12b) of the side surface (G12) of the first build-up part 10 is formed on an inner side of the side surface (G22) of the second build-up part 20 in plan view, while at the sidewall (S1), the side surface (G11) of the first build-up part 10 is formed on an outer side of the second portion (G21b) of the side surface (G21) of the second build-up part 20 in the wiring substrate (1a) in plan view. That is, in the X direction, the center-of-gravity position of the first build-up part 10 and the center-of-gravity position of the second build-up part 20 are offset from each other and do not overlap. Therefore, as described above with respect to the wiring substrate 1, it is inferred that occurrence of cracking of the core substrate 100 and the like can be suppressed. Similar to the wiring substrate 1, the wiring substrate (1a) may have a point-symmetrical shape with respect to the center of the core substrate 100 in a cross-section taken along its thickness direction.

In the wiring substrate (1b) of FIG. 3, similar to the wiring substrate 1 of FIG. 1, at the sidewall (S1), the first build-up part 10 has a side surface (G11) including a first portion (G11a) and a second portion (G11b), and the second build-up part 20 has a side surface (G21) including a first portion (G21a) and a second portion (G21b). The second portion (G21b) of the side surface (G21) of the second build-up part 20 is formed on an inner side of the side surface (G11) of the first build-up part 10 and the side surface (CS1) of the core substrate 100 in the wiring substrate (1b).

On the other hand, at the sidewall (S2), the second build-up part 20 has, similar to the second build-up part 20 of the wiring substrate (1a) in FIG. 2, an entirely flat side surface (G22) that is flush with the side surface (CS2) of the core substrate 100. The side surface (G22) is in contact with the side surface (CS2) of the core substrate 100 at one end and in contact with the surface (1S) of the wiring substrate (1b) at the other end. Further, at the sidewall (S2), the first build-up part 10 has a side surface (G12) that includes a first portion (G12a) and a second portion (G12b), similar to the first build-up part 10 of the wiring substrate 1 in FIG. 1. The second portion (G12b) of the side surface (G12) of the first build-up part 10 is formed on an inner side of the side surface (G22) of the second build-up part 20 and the side surface (CS2) of the core substrate 100 in the wiring substrate (1b).

In the wiring substrate (1b) as well, as described above with respect to the wiring substrate 1, it is thought that locations of stress concentration that may occur in the wiring substrate (1b) are dispersed to include a location indicated by the point (P1) and a location indicated by the point (P2). Therefore, it is thought that cracking in the core substrate 100 or peeling of each build-up part from the core substrate 100 can be suppressed.

Further, in the wiring substrate (1b) as well, at the sidewall (S2), the second portion (G12b) of the side surface (G12) of the first build-up part 10 is formed on an inner side of the side surface (G22) of the second build-up part 20 in plan view, while at the sidewall (S1), the second portion (G11b) of the side surface (G11) of the first build-up part 10 is formed on an outer side of the second portion (G21b) of the side surface (G21) of the second build-up part 20 in plan view. That is, in the X direction, the center-of-gravity position of the first build-up part 10 and the center-of-gravity position of the second build-up part 20 are offset from each other and do not overlap. Therefore, as described above with respect to the wiring substrate 1, it is inferred that occurrence of cracking of the core substrate 100 and the like can be suppressed.

### Method for Manufacturing Wiring Substrate

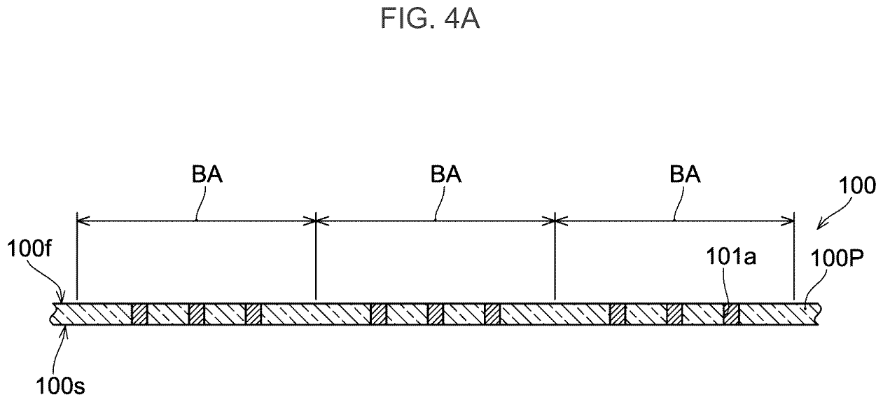

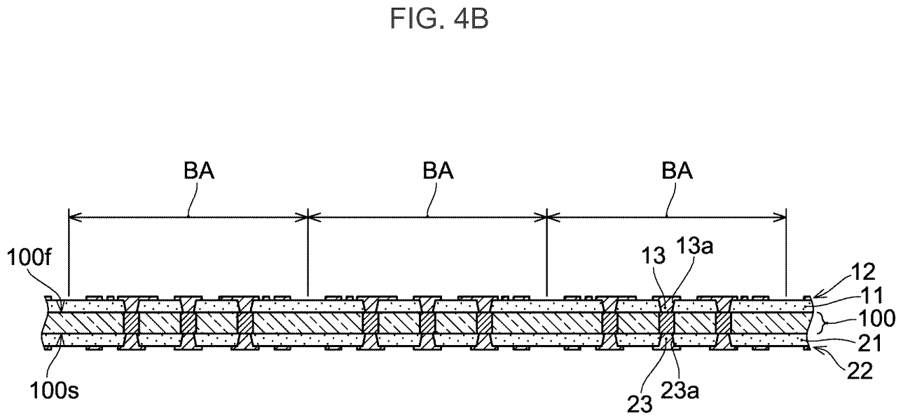

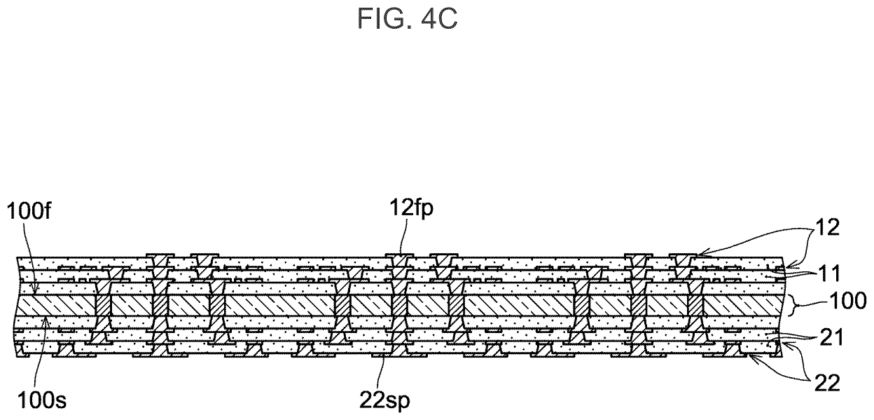

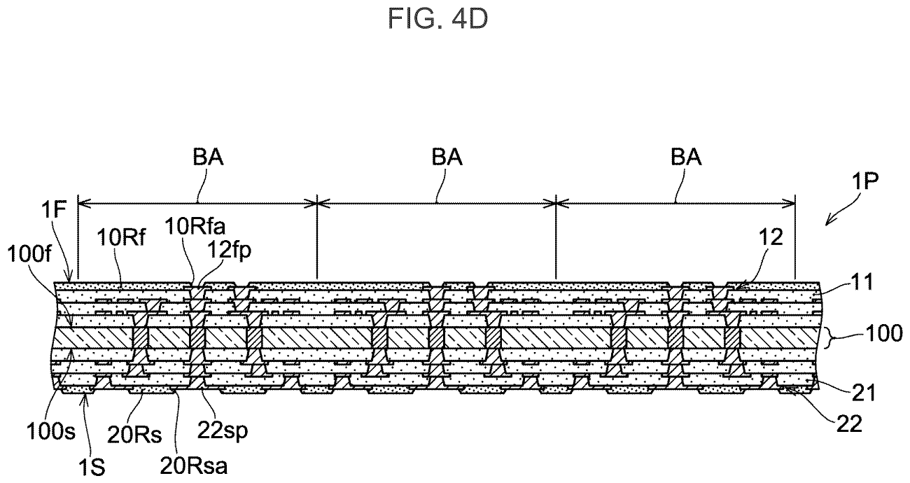

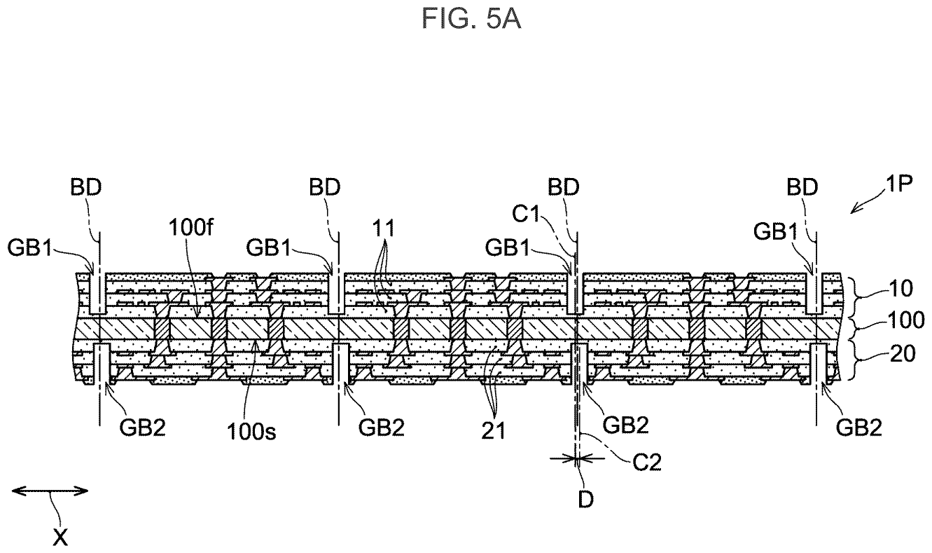

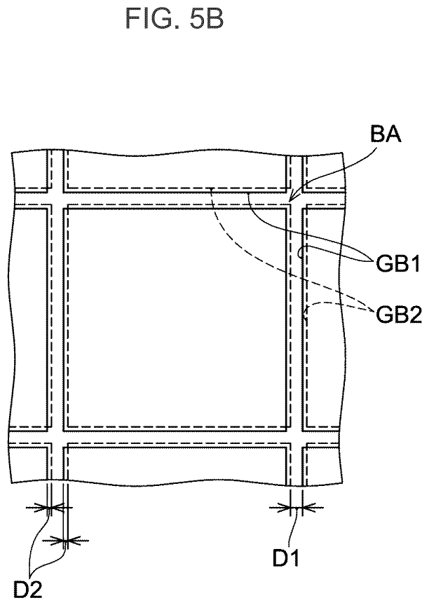

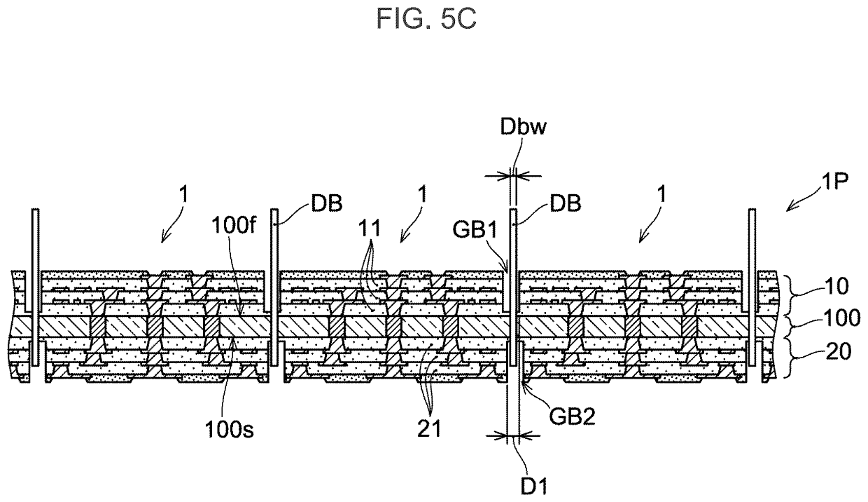

Next, with reference to FIGS. 4A to 4D and 5A to 5C, a method for manufacturing a wiring substrate according to an embodiment of the present invention is described using a case where the wiring substrate 1 illustrated in FIG. 1 is manufactured as an example.

Structural elements formed in the method for manufacturing the wiring substrate to be described below may be formed using the materials exemplified as the materials of the corresponding structural elements in the description of the wiring substrate 1 in FIG. 1, unless otherwise specified.

The method for manufacturing the wiring substrate of the embodiment includes forming a laminate that includes a core substrate, a first build-up part laminated on a first surface of the core substrate, and a second build-up part laminated on a second surface of the core substrate; and dividing the laminate into multiple wiring substrates. Here, the term “laminate” means multiple wiring substrates that are still in a connected state before being singulated. First, formation of a laminate (1P) (see FIG. 4D) is described with reference to FIGS. 4A to 4D.

As illustrated in FIG. 4A, a core substrate 100 is prepared. A material for the core substrate 100 is not particularly limited. However, FIG. 4A illustrates an example in which a glass plate (100P) containing, for example, soda-lime glass, borosilicate glass, alkali-free glass, or the like is used. Through holes (101a) are formed in the glass plate (100P). For example, modified portions are formed at positions in the glass plate (100P) where the through holes (101a) are to be formed by irradiation with laser light, and the through holes (101a) are formed by removing the modified portions using an etching solution containing, for example, hydrofluoric acid. As the laser light for forming the modified portions, a helium-neon laser, an argon ion laser, an excimer laser, various YAG lasers, and the like can be used.

After the formation of the through holes (101a), the through holes (101a) are filled with a conductive material, and a conductive material covering both surfaces of the glass plate (100P) orthogonal to its thickness direction is formed. For example, a first metal film (not illustrated) is formed on inner wall surfaces of the through holes (101a) and on both surfaces of the glass plate (100P) by electroless plating or sputtering, and then a second metal film (not illustrated) formed of a plating film is formed on the first metal film by electrolytic plating using the formed first metal film as a power feeding layer. Through conductors including the first and second metal films are formed in the through holes (101a), and both surfaces of the glass plate (100P) are covered with a conductive material having a two-layer structure formed of the first and second metal films. Subsequently, the conductive material layers covering both surfaces of the glass plate (100P) are removed, for example, by CMP (chemical mechanical polishing). As illustrated in FIG. 4A, the core substrate 100 is formed that has a first surface (100f) and a second surface (100s) on the opposite side with respect to the first surface (100f) and includes the glass plate (100P). The core substrate 100 includes multiple wiring substrate formation regions (BA) corresponding to connected multiple wiring substrates to be manufactured.

As illustrated in FIG. 4B, a first insulating layer 11 that covers the first surface (100f) of the core substrate 100 is laminated, and further, a first conductor layer 12 is formed on the first insulating layer 11. At the same time as the formation of the first conductor layer 12, first via conductors 13 are integrally formed with the first conductor layer 12. The first insulating layer 11 is laminated over the multiple wiring substrate formation regions (BA), and the first conductor layer 12 and the first via conductors 13 are formed in the wiring substrate formation regions (BA). Further, a second insulating layer 21 that covers the second surface (100s) of the core substrate 100 is formed, and further, a second conductor layer 22 is formed on the second insulating layer 21. At the same time as the formation of the second conductor layer 22, second via conductors 23 are integrally formed with the second conductor layer 22. The second insulating layer 21 is laminated over the multiple wiring substrate formation regions (BA), and the second conductor layer 22 and the second via conductors 23 are formed in the wiring substrate formation regions (BA).

The first insulating layer 11 and the second insulating layer 21 can be formed by thermocompression bonding of a film-like insulating resin (for example, epoxy resin) onto the surfaces (the first surface (100f) and the second surface (100s)) of the core substrate 100. Through holes (13a) are formed, for example by irradiation with CO₂ laser light, at positions in the first insulating layer 11 where the first via conductors 13 are to be formed. A metal film (not illustrated) is formed on inner surfaces of the through holes (13a) and on an upper surface of the first insulating layer 11 by electroless plating or sputtering, or the like. Using the formed metal film as a power feeding layer, an electrolytic plating film (not illustrated) is formed on the power feeding layer by pattern plating using electrolytic plating. As a result, the first conductor layer 12 and the first via conductors 13 are formed. Using the same methods as those for forming the first insulating layer 11, the first conductor layer 12, and the first via conductors 13, the second insulating layer 21, the second conductor layer 22, and the second via conductors 23 are formed on the second surface (100s) side of the core substrate 100.

As illustrated in FIG. 4C, on the upper side of the first surface (100f) of the core substrate 100, by repeating the same processes as those described above for forming the first insulating layer 11 and forming the first via conductors 13 and the first conductor layer 12, two additional sets of first insulating layer 11 and first conductor layer 12 are formed. Conductor pads (12fp) are provided in the outermost first conductor layer 12. Further, also on the upper side of the second surface (100s), by repeating the same processes as those for forming the second insulating layer 21 and forming the second via conductors 23 and the second conductor layer 22, two additional sets of second insulating layer 21 and second conductor layer 22 are formed. Conductor pads (22sp) are provided on the outermost second conductor layer 22. The processes for forming the insulating layers, the conductor layers, and the via conductors can be repeated a desired number of times in accordance with the number of conductor layers and insulating layers in wiring substrates to be manufactured.

As illustrated in FIG. 4D, a solder resist layer (10Rf) having openings (10Rfa) that expose the conductor pads (12fp) is formed, over the multiple wiring substrate formation regions (BA), on the outermost first conductor layer 12 and first insulating layer 11 on the first surface (100f) side of the core substrate 100. A solder resist layer (20Rs) having openings (20Rsa) that expose the conductor pads (22sp) is formed, over the multiple wiring substrate formation regions (BA), on the outermost second conductor layer 22 and second insulating layer 21 on the second surface (100s) side of the core substrate 100. The formation of the laminate (1P) is completed, which has a surface (1F) and a surface (1S) on an opposite side with respect to the surface (1F), and in which multiple wiring substrates are connected.

The process of dividing and sigulating the formed laminate (1P) into individual wiring substrates 1 is described below with reference to FIGS. 5A to 5C. FIG. 5B is a plan view of the laminate (1P), and illustrates one wiring substrate formation region (BA) of the laminate (1P) and its surrounding portion. In FIGS. 5A and 5B, boundaries (BD) between the multiple wiring substrates in the laminate (1P) are virtually indicated using one-dot chain lines. Dividing the laminate in the method for manufacturing the wiring substrate of the embodiment includes forming a first groove from the surface on the first build-up part side of the laminate; forming a second groove from the surface on the second build-up part side of the laminate; and cutting the core substrate along the first groove or the second groove.

First, as illustrated in FIGS. 5A and 5B, a first groove (GB1) is formed along the boundaries (BD) between the multiple wiring substrates 1 by penetrating the first build-up part 10 in the thickness direction of the laminate (1P) from the surface on the first build-up part 10 side of the laminate (1P). Further, a second groove (GB2) is formed along the boundaries (BD) by penetrating the second build-up part 20 in the thickness direction of the laminate (1P) from the surface on the second build-up part 20 side of the laminate (1P). The first groove (GB1) and the second groove (GB2) may be formed at the same time, or one may be formed before the other.

The first groove (GB1) and the second groove (GB2) may be formed, for example, by irradiating laser light, such as CO₂ laser light, from outside of the first build-up part 10 or the second build-up part 20 to the laminate (1P). Further, the first groove (GB1) and the second groove (GB2) may be formed by cutting the first build-up part 10 or the second build-up part 20 using a dicing blade typically used in ordinary dicing, for example, a diamond blade in which diamond abrasive grains are embedded in resin. The first groove (GB1) and the second groove (GB2) are preferably formed, as illustrated in FIG. 5B, over an entire peripheral edge of each wiring substrate formation region (BA) so as to surround each wiring substrate formation region (BA) in plan view.

In the method for manufacturing the wiring substrate of the embodiment, as illustrated in FIGS. 5A and 5B, the first groove (GB1) and the second groove (GB2) are formed such that, in a width direction of the first groove (GB1) and the second groove (GB2), a center (C1) of the first groove (GB1) and a center (C2) of the second groove (GB2) are offset from each other. The “width direction” of the first groove (GB1) and the second groove (GB2) is a direction orthogonal to the direction in which the grooves extend, and in FIG. 5A this is an X direction indicated by an arrow (X). That is, in the method for manufacturing the wiring substrate of the embodiment, the first groove (GB1) and the second groove (GB2) are formed such that the center (C1) in the width direction of the first groove (GB1) and the center (C2) in the width direction of the second groove (GB2) do not overlap in plan view. In other words, at least one of the first groove (GB1) and the second groove (GB2) formed using the method for manufacturing the wiring substrate of the embodiment has, in the width direction of the first groove (GB1) and the second groove (GB2), a portion that at least partially does not overlap with the other in plan view.

In the method for manufacturing the wiring substrate of the embodiment, since the first groove (GB1) and the second groove (GB2) are formed in this manner, it is thought that unintended cleaving of the laminate (1P) during the manufacturing process of the wiring substrate can be suppressed. That is, when the first groove (GB1) and the second groove (GB2) formed with the core substrate 100 interposed therebetween completely overlap in plan view, stress generated by external mechanical impact or the like tends to concentrate at the same position in plan view on both the front and back surfaces of the core substrate. Therefore, there is a concern that the core substrate 100, or the entire laminate (1P), may be cleaved between such stress concentration locations that occur at the same position in plan view. Further, when the grooves are sequentially formed on the front and back surfaces of the core substrate 100, there is also a concern that stress generated during formation of the later-formed groove may concentrate between the groove being formed and the previously formed groove formed at the same position in plan view, thereby causing unintended cracking in the core substrate or the laminate.

To address such concerns, in the method for manufacturing the wiring substrate of the embodiment, both grooves are formed such that the center (C1) of the first groove (GB1) and the center (C2) of the second groove (GB2) do not overlap in plan view. Therefore, stress concentration between the two grooves during the manufacturing process, as described above, is alleviated. As a result, it is thought that occurrence of unintended cracking in the core substrate 100 or the laminate (1P) can be suppressed. In particular, when the core substrate 100 includes a glass plate that is hard and therefore relatively brittle, the method for manufacturing the wiring substrate of the embodiment is thought to be effectively applicable to the manufacture of the wiring substrate.

In the example illustrated in FIGS. 5A and 5B, among the first groove (GB1) and the second groove (GB2), the first groove (GB1) is formed so as to partially overlap with the second groove (GB2) in plan view, and the second groove (GB2) is also formed so as to partially overlap with the first groove (GB1) in plan view. The first groove (GB1) and the second groove (GB2) have: a length (D1) (see FIG. 5B) of a portion where widths of the first groove (GB1) and the second groove (GB2) overlap in plan view; and a length (D2) (see FIG. 5B) of a portion where the widths of the first groove (GB1) and the second groove (GB2) do not overlap in plan view. The width of the first groove (GB1) and the width of the second groove (GB2) are, for example, 400 μm to 600 μm, and may be the same as or different from each other. Further, a length (D) of the offset in the width direction between the position of the center (C1) of the first groove portion (GB1) and the position of the center (C2) of the second groove portion (GB2) (see FIG. 5A; the length (D) is also referred to as an “offset amount (D)” below) may be, for example, 50 μm to 300 μm. When the first groove (GB1) and the second groove (GB2) are formed with such a degree of overlap or with such an offset amount (D), it is thought that the effect of preventing cracking of the core substrate 100 or the like during the above-described process can be obtained. In addition, in the cutting process to be described later, the core substrate 100 can be easily cut at the portion where the first groove (GB1) and the second groove (GB2) overlap, and therefore the laminate (1P) can be easily divided.

Further, in the example of FIG. 5A, the first groove (GB1) is formed so as not to reach the first surface (100f) of the core substrate 100. The first groove (GB1) exposes, at its bottom surface, the first insulating layer 11 that is directly formed on the first surface (100f) of the core substrate 100 among the multiple first insulating layers 11 constituting the first build-up part 10. Similarly, the second groove (GB2) is formed so as not to reach the second surface (100s) of the core substrate 100. The second groove (GB2) exposes, at its bottom surface, the second insulating layer 21 that is directly formed on the second surface (100s) of the core substrate 100 among the multiple second insulating layers 21 constituting the second build-up part 20.

In the method for manufacturing the wiring substrate of the embodiment, forming the first groove (GB1) may include exposing the first insulating layer 11 constituting the first build-up part 10 at the bottom surface of the first groove (GB1). Further, forming the second groove (GB2) may include exposing the second insulating layer 21 constituting the second build-up part 20 at the bottom surface of the second groove (GB2). Since the first groove (GB1) is formed such that the first insulating layer 11 is exposed at the bottom surface, the first surface (100f) of the core substrate 100 remains covered by the first insulating layer 11 even after the first groove (GB1) has been formed. Further, since the second groove (GB2) is formed such that the second insulating layer 21 is exposed at the bottom surface, the second surface (100s) of the core substrate 100 remains covered by the second insulating layer 21 even after the second groove (GB2) has been formed. Therefore, the surfaces of the core substrate 100, which may include a glass plate, can be protected from an external load by the insulating layers.

After the first groove (GB1) and the second groove (GB2) are formed, as illustrated in FIG. 5C, the laminate (1P) is cut from the first groove (GB1) side along the first groove (GB1). That is, the remaining portion of the first build-up part 10, the core substrate 100, and the remaining portion of the second build-up part 20 are cut. In the example of FIG. 5C, specifically, the first insulating layer 11 directly formed on the first surface (100f) of the core substrate 100, the core substrate 100, and the second insulating layer 21 directly formed on the second surface (100s) of the core substrate 100 are continuously cut. Although FIG. 5C illustrates an example in which the laminate (1P) is cut from the first groove (GB1) side, the remaining portion of the second build-up part 20, the core substrate 100, and the remaining portion of the first build-up part 10 may be cut from the second groove (GB2) side along the second groove (GB2).

The cutting of the laminate (1P) along the first groove (GB1) or the second groove (GB2) can be performed, for example, using a dicing blade (DB). For example, a diamond blade in which diamond abrasive grains are embedded in resin may be used.

Alternatively, the laminate (1P) may be cut by cleaving the core substrate 100 and the like by scribing using an appropriate scribing device. By completely cutting the core substrate 100 and the first and second build-up parts (10, 20), the multiple connected wiring substrates 1 are completely separated and singulated into individual wiring substrates 1.

When a laminate having build-up parts formed on both surfaces of a core substrate is continuously cut from one surface to the other surface using a dicing blade, defects such as cracking in the core substrate or peeling between the core substrate and the build-up parts may occur. That is, it is thought that frictional heat is generated by friction between the dicing blade and the laminate during the cutting process from one surface of the laminate to the core substrate. Therefore, when the dicing blade comes into contact with the core substrate, thermal stress may concentrate near an interface between the build-up part and the core substrate in a vicinity of the dicing blade. Due to this concentration of thermal stress, cracking may occur in the core substrate when the dicing blade contacts the core substrate, and peeling between the build-up part and the core substrate may also occur.

In contrast, in the method for manufacturing the wiring substrate of the embodiment, before the core substrate 100 is cut, the first groove (GB1) is formed in the first build-up part 10, and the second groove (GB2) is formed in the second build-up part 20. Therefore, for example, when the laminate (1P) is cut from the first build-up part 10 side, it is thought that concentration of thermal stress near an interface between the first build-up part 10 and the core substrate 100 when the dicing blade (DB) contacts the core substrate 100 is suppressed. Further, since the second groove (GB2) has been formed, a cutting length of the second build-up part 20 is shortened, and thus, it is thought that an amount of frictional heat generated during cutting of the second build-up part 20 is small. That is, it is thought that concentration of thermal stress at the interface between the core substrate 100 and the second build-up part 20 due to heat generation during cutting of the second build-up part 20 is also unlikely to occur. Similarly, when the laminate (1P) is cut from the second build-up part 20 side, it is thought that concentration of thermal stress at the interface between the core substrate 100 and each build-up part is unlikely to occur.

Therefore, in singulating the laminate (1P), occurrence of cracking in the core substrate 100, peeling of each build-up part from the core substrate 100, or the like is suppressed. Even when the laminate (1P) is cut by scribing, since each groove is formed in advance, a force required for cutting is reduced, and stress applied to the core substrate 100 is reduced, and thus it is thought that occurrence of cracking or the like is suppressed.

In addition, as described above, in the method for manufacturing the wiring substrate of the embodiment, since both the first groove (GB1) and the second groove (GB2) are formed such that their centers do not overlap in plan view, it is thought that occurrence of unintended cracking in the core substrate 100 or the laminate (1P) is suppressed. Therefore, it is thought that occurrence of in-process defects is suppressed, process quality is improved, and wiring substrates are stably manufactured.

In the example illustrated in FIG. 5C, the dicing blade (DB) has a width (Dbw) that is smaller than the length (D1) of the portion where the first groove (GB1) and the second groove (GB2) overlap in plan view in the width direction. Then, the laminate (1P) is cut by the dicing blade (DB) that is aligned so as to pass through the portion where the first groove (GB1) and the second groove (GB2) overlap in plan view in the width direction. By cutting the laminate (1P) as in the example of FIG. 5C, steps can be provided between a cut surface of the core substrate 100 and a wall surface exposed in the first groove (GB1) and a wall surface exposed in the second groove (GB2), similar to the steps that the second portion (G11b) of the side surface (G11) and the second portion (G21b) of the side surface (G21) have relative to the side surface (CS1) of the core substrate 100 in the wiring substrate 1 of FIG. 1.

By cutting the core substrate 100 as in the example of FIG. 5C, the wiring substrate 1 having side surfaces with steps at sidewalls, as in the wiring substrate 1 in the example of FIG. 1, is completed. Thus, in the method for manufacturing the wiring substrate of the embodiment, cutting the core substrate 100 may include forming, in the core substrate 100, a cut surface having steps relative to a wall surface exposed in the first groove (GB1) and a wall surface exposed in the second groove (GB2).

### Modified Examples of Formation of First Groove and Second Groove

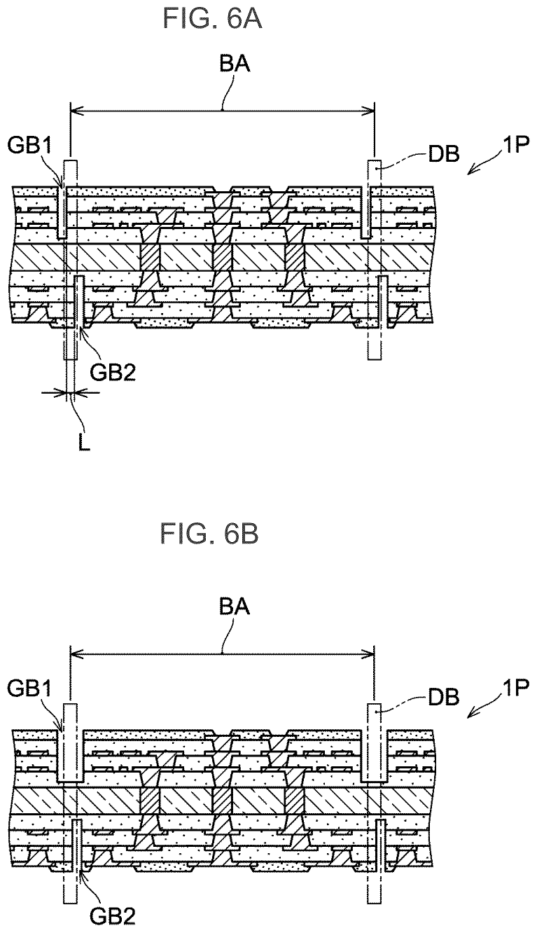

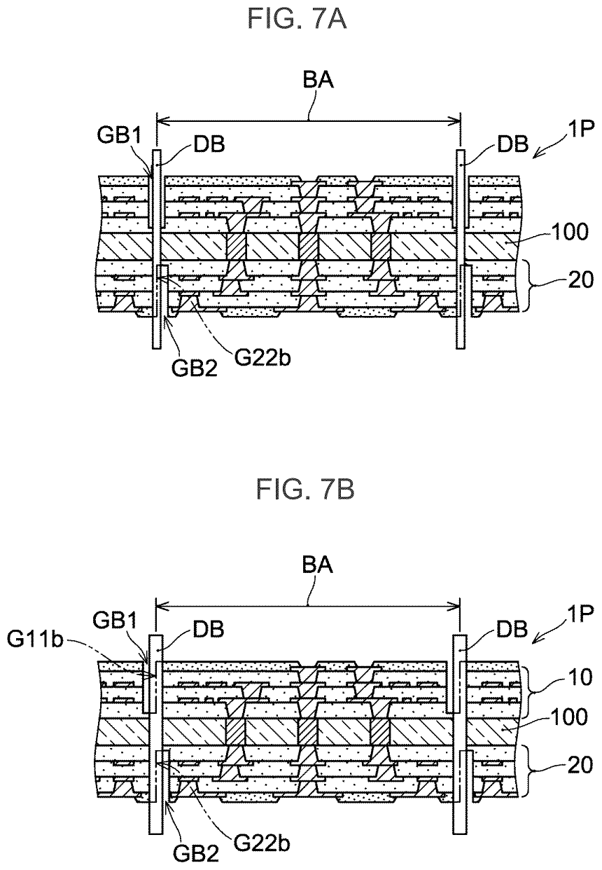

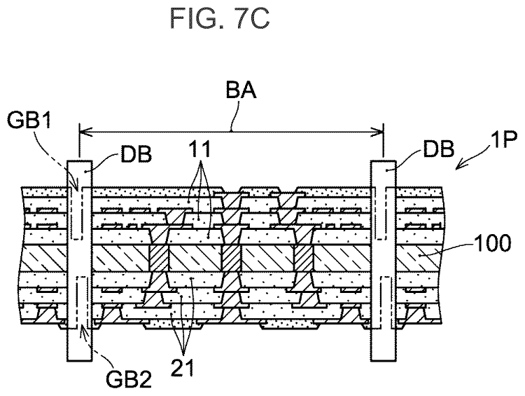

FIGS. 6A and 6B respectively illustrate a first modified example and a second modified example regarding the formation of the first groove (GB1) and the second groove (GB2) in the method for manufacturing the wiring substrate of the embodiment. FIGS. 6A and 6B, as well as FIGS. 7A to 7C to be referred to later, each illustrate an enlarged view of only one wiring substrate formation region (BA) and a nearby portion thereof in the laminate (1P).

In the first modified example illustrated in FIG. 6A, the first groove (GB1) and the second groove (GB2) are formed at positions that do not overlap at all in plan view. That is, the first groove (GB1) and the second groove (GB2) are formed with a distance (L) between each other in plan view, meaning that the center of the first groove (GB1) and the center of the second groove (GB2) are distinctly offset from each other. Therefore, even when the first groove (GB1) and the second groove (GB2) are formed so as not to overlap at all, it is thought that unintended cleaving of the laminate (1P) during the manufacturing process of the wiring substrate is suppressed.

As illustrated in FIG. 6A, the laminate (1P) in which the first groove (GB1) and the second groove (GB2) have been formed is cut, for example, using a dicing blade (DB), such as the dicing blade (DB) indicated by a two-dot chain line, that is positioned so as to span the region between the first groove (GB1) and the second groove (GB2) in plan view. By cutting the laminate (1P) as illustrated in FIG. 6A, for example, a wiring substrate having side surfaces such as those of the wiring substrate (1a) illustrated in FIG. 2 can be formed.

In the second modified example illustrated in FIG. 6B, a first groove (GB1) and a second groove (GB2) having mutually different widths are formed. Further, the second groove (GB2) is formed so as to entirely overlap the first groove (GB1) in plan view. However, also in the present modified example, the first groove (GB1) and the second groove (GB2) are formed such that the center of the first groove (GB1) and the center of the second groove (GB2) do not overlap in plan view. Therefore, also in the present modified example, it is thought that unintended cleaving of the laminate (1P) during the manufacturing process of the wiring substrate 1 is suppressed. As illustrated in FIG. 6B, the laminate (1P) in which the first groove (GB1) and the second groove (GB2) have been formed can be cut using a dicing blade (DB) that is positioned so as to at least partially overlap in plan view with the narrower of the two grooves (the second groove (GB2) in the example of FIG. 6B).

As in the second modified example of FIG. 6B, in the method for manufacturing the wiring substrate of the embodiment, one of the first groove (GB1) and the second groove (GB2) may be formed to have a width different from that of the other. Further, one of the first groove (GB1) and the second groove (GB2) may be formed so as to entirely overlap the other in plan view. In addition, as in the example illustrated in FIG. 5A referred to earlier, one of the first groove (GB1) and the second groove (GB2) may be formed so as to partially overlap the other in plan view. That is in the method for manufacturing the wiring substrate of the embodiment, one of the first groove (GB1) and the second groove (GB2) may be formed so as to at least partially overlap the other in plan view.

### Modified Examples of Cutting of Laminate

FIGS. 7A to 7C respectively illustrate first to third modified examples regarding the cutting of the laminate (1P) in the method for manufacturing the wiring substrate of the embodiment. In the first modified example illustrated in FIG. 7A, the dicing blade (DB) is positioned so as to overlap in plan view with one of two opposing wall surfaces of one of the first groove (GB1) and the second groove (GB2), which are formed such that their center positions in the width direction do not overlap each other in plan view.

Specifically, in FIG. 7A, the dicing blade (DB) is positioned so as to overlap in plan view with one (the wall surface (G22b) on the left side in FIG. 7A) of the two opposing wall surfaces of the second groove (GB2). However, the dicing blade (DB) has a width narrower than that of the first groove (GB1) and is positioned so as to be entirely accommodated inside the first groove (GB1) in plan view. The laminate (1P) is cut using the dicing blade (DB) positioned in this manner.

When the dicing blade (DB) is positioned as in the first modified example, the dicing blade (DB) moves in the thickness direction of the laminate (1P), while shaving the wall surface (G22b) of the second groove (GB2), and the laminate (1P) including the core substrate 100 is cut. By cutting the laminate (1P) in this way, it is possible to form, on one of two opposing sidewalls of a manufactured wiring substrate, a cut surface in the second build-up part 20 that is flush with a cut surface of the core substrate 100. For example, a wiring substrate having side surfaces as those of the wiring substrate (1b) illustrated in FIG. 3 can be formed. In the method for manufacturing the wiring substrate of the embodiment, cutting the core substrate may include, as in the first modified example, shaving a wall surface exposed in at least one of the first groove and the second groove.

In the second modified example illustrated in FIG. 7B, the dicing blade (DB) is positioned so as to overlap in plan view with one of the two opposing wall surfaces of each of the first groove (GB1) and the second groove (GB2), which are formed such that their center positions in the width direction do not overlap each other in plan view.

Specifically, in FIG. 7B, the dicing blade (DB) is positioned so as to overlap in plan view with one of the two opposing wall surfaces of the first groove (GB1) (the right-side wall surface (G11b) in FIG. 7B) and one of the two opposing wall surfaces of the second groove (GB2) (the left-side wall surface (G22b) in FIG. 7B). The laminate (1P) is cut using the dicing blade (DB) positioned in this manner.

When the dicing blade (DB) is positioned as in the second modified example, the dicing blade (DB) moves in the thickness direction of the laminate (1P) while successively shaving the wall surface (G11b) of the first groove (GB1) and the wall surface (G22b) of the second groove (GB2), and the laminate (1P) including the core substrate 100 is cut.

By cutting the laminate (1P) in this way, it is possible to form, on one of two opposing sidewalls of a manufactured wiring substrate, a cut surface in the first build-up part 10 that is flush with a cut surface of the core substrate 100. Further, it is possible to form, on the other sidewall, a cut surface in the second build-up part 20 that is flush with a cut surface of the core substrate 100. For example, a wiring substrate having side surfaces as those of the wiring substrate (1a) illustrated in FIG. 2 can be formed. In the method for manufacturing the wiring substrate of the embodiment, cutting the core substrate may include, as in the second modified example, forming, in each of both the first build-up part 10 and the second build-up part 20, a cut surface that is flush with a cut surface of the core substrate 100.

In the third modification shown in FIG. 7C, the laminate (1P) is cut using a dicing blade (DB) that is positioned so as to entirely overlap, in plan view, with both the first groove (GB1) and the second groove (GB2), which are formed such that their center positions in the width direction do not overlap in plan view. When the dicing blade (DB) is positioned as in the present modified example, the dicing blade (DB) moves in the thickness direction of the laminate (1P) while successively shaving the first insulating layers 11 around the first groove (GB1) and the second insulating layers 21 around the second groove (GB2), and the laminate (1P) including the core substrate 100 is cut. By cutting the laminate (1P) in this way, it is possible to manufacture a wiring substrate in which the cut surfaces of the first build-up part 10, the second build-up part 20, and the core substrate 100 are exposed flus on both opposing sidewalls. That is, it is thought that a wiring substrate requiring flat side surfaces can be manufactured with stable process quality by suppressing occurrence of unintended cracking of the core substrate during the manufacturing process.

The wiring substrate of the embodiment is not limited to those having the structures and shapes illustrated in the drawings and those having the structures, shapes, and materials exemplified in the present specification. As described above, the wiring substrate of the embodiment can have any laminated structure. The wiring substrate of the embodiment may have any number of conductor layers and insulating layers. Each conductor layer can include any conductor patterns. The solder resist layers may be omitted. The thicknesses of the thin layer portions on the surfaces of the core substrate may differ between the first build-up part side and the second build-up part side.

The method for manufacturing the wiring substrate of the embodiment is not limited the method described with reference to the drawings. For example, the methods of forming the insulating layers and the conductor layers formed on the insulating layers are not limited to the methods described with reference to FIGS. 4A to 4D. The conductor layers may be formed using a method other than a semi-additive method, such as a full-additive method. The first groove and the second groove may have different depths. In the method for manufacturing the wiring substrate of the embodiment, it is also possible that any process other than the processes described above is added, or some of the processes described above are omitted.

Japanese Patent Application Laid-Open Publication No. 2015-231005 describes a method for manufacturing a wiring substrate that includes cutting a substrate, in which resin layers are formed on both surfaces of a glass substrate, into multiple individual wiring substrates along dicing lines using a dicing blade.

In the method for manufacturing a wiring substrate described in Japanese Patent Application Laid-Open Publication No. 2015-231005, in the process of cutting the substrate with a dicing blade, defects such as occurrence of cracks in the glass substrate and peeling of the resin layers from the glass substrate may occur. Further, in a wiring substrate manufactured using the manufacturing method described in Japanese Patent Application Laid-Open Publication No. 2015-231005, peeling of the resin layers from the glass substrate may occur, for example, due to an external load during use.

A method for manufacturing a wiring substrate according to an embodiment of the present invention includes: forming a laminate that includes: a core substrate having a first surface and a second surface on an opposite side with respect to the first surface; a first build-up part laminated on the first surface; and a second build-up part laminated on the second surface; and dividing the laminate into multiple wiring substrates. The dividing of the laminate includes: forming a first groove from a surface of the laminate on the first build-up part side; forming a second groove from a surface of the laminate on the second build-up part side; and cutting the core substrate along the first groove or the second groove. The first groove and the second groove are formed such that centers of the first groove and the second groove are offset from each other in a width direction of the first groove and the second groove.

A wiring substrate according to an embodiment of the present invention includes: a core substrate that has a first surface and a second surface on an opposite side with respect to the first surface; a first build-up part that is laminated on the first surface; and a second build-up part that is laminated on the second surface. At least a portion of a side surface of one of the first build-up part and the second build-up part is formed on an inner side of a side surface of the other one of the first build-up part and the second build-up part in the wiring substrate in plan view.

According to a method for manufacturing a wiring substrate of an embodiment of the present invention and a wiring substrate of an embodiment of the present invention, it is thought that occurrence of cracking in the core substrate, peeling of the build-up parts from the core substrate, and the like can be suppressed during the process of dividing the laminate into multiple wiring substrates, in subsequent processes after the dividing process, and during use of the wiring substrate.

Obviously, numerous modifications and variations of the present invention are possible in light of the above teachings. It is therefore to be understood that within the scope of the appended claims, the invention may be practiced otherwise than as specifically described herein.

1. A method for manufacturing a wiring substrate, comprising:
forming a laminate comprising a core substrate, a first build-up part, and a second build-up part;
forming a first groove on the laminate from a surface of the laminate on a first build-up part side such that the first groove is formed in the first build-up part;
forming a second groove on the laminate from a surface of the laminate on a second build-up part side such that the second groove is formed in the second build-up part and has a center of a width that is offset from a center of a width of the first groove; and
cutting the core substrate in the laminate along one of the first groove in the first build-up part and the second groove in the second build-up part such that the laminate is divided into a plurality of wiring substrates,
wherein the laminate is formed such that the first build-up part is formed on a first surface of the core substrate and that the second build-up part is formed on a second surface of the core substrate on an opposite side with respect to the first surface of the core substrate.

2. The method for manufacturing a wiring substrate according to claim 1, wherein the core substrate includes a glass plate.

3. The method for manufacturing a wiring substrate according to claim 1, wherein the first groove and the second groove are formed such that the first groove and the second groove at least partially overlap each other.

4. The method for manufacturing a wiring substrate according to claim 3, wherein the first groove and the second groove are formed such that the first groove and the second groove partially overlap each other.

5. The method for manufacturing a wiring substrate according to claim 1, wherein the forming of the first groove includes exposing an insulating layer in the first build-up part at a bottom surface of the first groove, and the forming of the second groove includes exposing an insulating layer in the second build-up part at a bottom surface of the second groove.

6. The method for manufacturing a wiring substrate according to claim 1, wherein one of the first groove and the second groove is formed to have a width different from a width of the other one of the first groove and the second groove.

7. The method for manufacturing a wiring substrate according to claim 1, wherein the cutting of the core substrate in the laminate includes shaving a wall surface exposed in at least one of the first groove and the second groove.

8. The method for manufacturing a wiring substrate according to claim 7, wherein the cutting of the core substrate in the laminate includes forming a cut surface that is flush with a cut surface of the core substrate in the first build-up part and the second build-up part.

9. The method for manufacturing a wiring substrate according to claim 1, wherein the cutting of the core substrate in the laminate includes forming a cut surface having a step relative to at least one of a wall surface exposed in the first groove and a wall surface exposed in the second groove in the core substrate.

10. The method for manufacturing a wiring substrate according to claim 1, wherein the cutting of the core substrate in the laminate includes cutting the core substrate in the laminate by a dicing blade.

11. The method for manufacturing a wiring substrate according to claim 1, wherein the cutting of the core substrate in the laminate includes cleaving the core substrate in the laminate by scribing.

12. The method for manufacturing a wiring substrate according to claim 2, wherein the first groove and the second groove are formed such that the first groove and the second groove at least partially overlap each other.

13. The method for manufacturing a wiring substrate according to claim 12, wherein the first groove and the second groove are formed such that the first groove and the second groove partially overlap each other.

14. The method for manufacturing a wiring substrate according to claim 2, wherein the forming of the first groove includes exposing an insulating layer in the first build-up part at a bottom surface of the first groove, and the forming of the second groove includes exposing an insulating layer in the second build-up part at a bottom surface of the second groove.

15. The method for manufacturing a wiring substrate according to claim 2, wherein one of the first groove and the second groove is formed to have a width different from a width of the other one of the first groove and the second groove.

16. The method for manufacturing a wiring substrate according to claim 2, wherein the cutting of the core substrate in the laminate includes shaving a wall surface exposed in at least one of the first groove and the second groove.

17. A wiring substrate, comprising:
a core substrate;
a first build-up part laminated on a first surface of the core substrate; and
a second build-up part laminated on a second surface of the core substrate on an opposite side with respect to the first surface of the core substrate,
wherein at least a portion of a side surface of one of the first build-up part and the second build-up part is formed on an inner side of a side surface of the other one of the first build-up part and the second build-up part.

18. The wiring substrate according to claim 17, wherein the core substrate includes a glass plate.

19. The wiring substrate according to claim 17, wherein a side surface of the core substrate has a side surface protruding beyond at least a portion of the side surface of the first build-up part and at least a portion of the side surface of the second build-up part.

20. The wiring substrate according to claim 17, wherein the wiring substrate has two opposing sidewalls formed such that at least a portion of a side surface of the first build-up part is formed on an inner side of a side surface of the second build-up part at one of the two opposing sidewalls and that a side surface of the first build-up part is formed on an outer side of at least a portion of a side surface of the second build-up part at the other of the two opposing sidewalls.
